(19) United States
(12) Patent Application Publication
(10) Pub. No.: US 2008/0230864 A1
(43) Pub. Date: Sep. 25, 2008

(54) Image Sensor and Method for Manufacturing the Same

(76) Inventor: MIN HYUNG LEE, Cheongjoo-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,819

(22) Filed: Aug. 21, 2007

(30) Foreign Application Priority Data
Mar. 19, 2007 (KR) 10-2007-0026401

(51) Int. Cl. H01L 31/00; H01L 21/02

(52) U.S. Cl. 257/448; 438/73; 257/E31.113; 257/E21.598

(57) ABSTRACT

Disclosed is an image sensor which includes a plurality of pixel patterns formed on corresponding metal interconnections of an interlayer dielectric and a dummy pixel pattern formed between adjacent pixel patterns of the plurality of the pixel patterns. The dummy pixel patterns are not formed connected to the metal interconnections. The dummy pixel patterns can be formed spaced a distance apart from the plurality of pixel patterns such that air gaps form between the dummy pixel patterns and the pixel patterns in an intrinsic layer that is formed on the dummy pixel pattern and the plurality of pixel patterns.

### CROSS-REFERENCE TO RELATED APPLICATION

The present application claims the benefit under 35 U.S.C. § 119 of Korean Patent Application No. 10-2007-0026401, filed Mar. 19, 2007, which is hereby incorporated by reference in its entirety.

### BACKGROUND

Image sensors are semiconductor devices for converting an optical image into an electrical signal, and are generally classified as a charge coupled device (CCD) image sensor or a complementary metal oxide silicon (CMOS) image sensor (CIS).

The CCD has various disadvantages such as a complicated drive mode and high power consumption. Also, the CCD requires multi-step photo processes, and thus has a complicated manufacturing process. For this reason, the CIS has recently been spotlighted as a next-generation image sensor capable of overcoming the disadvantages of the CCD.

The CIS includes a photodiode and a MOS transistor in each unit pixel, from which the electric signals sequentially are detected in a switching mode to realize images.

In manufacturing such image sensors, efforts have been made to improve photo sensitivity of the image sensor. One of the efforts leads to technology of collecting light.

For example, the CIS includes a photo sensing portion for sensing light and a logic circuit portion for processing the sensed light into an electrical signal. In order to improve the photosensitivity, an effort has been made to increase the ratio (called “fill factor”) of an area of the photo sensing portion to an entire area of the image sensor. However, since the logic portion cannot be removed, the ability to increase the fill factor is limited under the restricted area.

In the case of high-pixel CISs currently used for mobile phones or other portable appliances, a photodiode serving to receive light and convert the received light into an electrical signal is located below a metal interconnection in the CIS, so that the transmittance of the incident light is decreased.

Such a CIS has a structure in which interlayer dielectric films are sequentially stacked on light-receiving elements formed on a substrate, a metal interconnection is formed between the interlayer dielectric films, and a passivation layer, a color filter layer, a planarization layer, and a micro lens are sequentially formed on the metal interconnection.

As demand for the high-pixel CISs are increased, the size of each unit pixel is reduced more and more. As a result, the amount of light incident onto the photodiode, which is the light receiving element, is decreased.

In addition, since a plurality of insulating layers are stacked on the photodiode, the light, which is focused through the micro-lens, is reflected and absorbed on the interfaces between the insulating layers, thereby lowering the photosensitivity.

In addition, the light passing through an edge of the micro-lens does not reach the light receiving element, but is transferred to the metal interconnection or pixels adjacent to the light-receiving element, so that crosstalk occurs between the pixels, degrading the photosensitivity.

### BRIEF SUMMARY

Embodiments of the present invention provide an image sensor including a transistor circuit and a photodiode and a method of manufacturing the image sensor where the transistor circuit and the photodiode are vertically stacked.

An image sensor according to an embodiment includes a semiconductor substrate having a circuit region, an interlayer dielectric formed on the semiconductor substrate and including a plurality of metal interconnections, and a plurality of pixel patterns connected with the metal interconnections, where each pixel pattern can include a lower electrode and a first conductive layer. The image sensor also includes a dummy pixel pattern formed between adjacent pixel patterns of the plurality of pixel patterns.

In addition, a method of manufacturing an image sensor according to an embodiment includes forming an interlayer dielectric including a plurality of metal interconnections on a semiconductor substrate having a circuit region, forming a lower electrode layer and a first conductive layer on the interlayer dielectric, forming a plurality of pixel patterns connected with the plurality of metal interconnections by etching the lower electrode and the first conductive layer, and forming a dummy pixel pattern between the pixel patterns when forming the pixel patterns.

### BRIEF DESCRIPTION OF THE DRAWINGS

FIGS. 1 to 6 are cross-sectional views representing a manufacturing process of an image sensor according to an embodiment of the present invention.

### DETAILED DESCRIPTION

Hereinafter, an image sensor and a method of manufacturing the same according to embodiments of the present invention will be described with reference to the accompanying drawings.

In the following description of embodiments, when it is expressed that one layer is formed “on/over” some other layer, it means that the layer is directly formed “on/over” the other layer or indirectly formed “on/over” the other layer such that another layer is interposed therebetween.

FIG. 6 is a cross-sectional view of an image sensor according to an embodiment.

Referring to FIG. 6, an image sensor according to an embodiment can include a lower interconnection structure 20 having a plurality of lower interconnections 21 formed on a semiconductor substrate 10 having a circuit region (not shown).

An interlayer dielectric 30 including a metal interconnection 31 can be formed on the lower interconnection structure 20.

A pixel pattern A, can connect to the metal interconnection 31 and can have a stacked structure including a lower electrode 41 and a first conductive layer pattern 51. The pixel pattern A can be formed on the interlayer dielectric 30.

The lower electrode 41 of the pixel pattern can be formed, for example, of Cr, Ti, Ta, TiW, or Al. According to some embodiments, the lower electrode 41 has a thickness of 100 Å to 5000 Å.

The first conductive layer pattern 51 of the pixel pattern can be formed, for example, of amorphous silicon doped with n-type dopants. In addition, according to some embodiments, the first conductive layer pattern 51 has a thickness of 10 Å to 1000 Å.

A dummy pixel pattern B, which is not connected to a metal interconnection 31 but isolated from the metal interconnection 31, can be formed between adjacent pixel patterns A. The dummy pixel pattern B can be formed of the same material as that of the pixel pattern A, and can have a structure the same as that of the pixel pattern A.

An intrinsic layer 61 and a second conductive layer 70 can be formed on the interlayer dielectric 30 on which the pixel pattern A and the dummy pixel pattern B are formed. In particular, according to embodiments of the present invention, when the intrinsic layer 61 is formed, an air gap 100 having an air layer may be formed between the pixel pattern A and the dummy pixel pattern B.

For example, the intrinsic layer 61 can be formed of an amorphous silicon layer having a thickness of 1000 Å to 20,000 Å, and the second conductive layer 70 can be formed of p-doped amorphous silicon having a thickness of 50 Å to 5000 Å.

An ITO (Indium Tin Oxide) layer can be formed on the second conductive layer 70 to serve as an upper electrode 80.

The image sensor can improve light transmittance by providing the photodiode above a metal interconnection.

In addition, according to an embodiment the image sensor can have pixel patterns separated from each other by dummy pixel patterns (which are insulated from the metal interconnection) formed between the pixel patterns.

In addition, an air gap can be formed between the pixel pattern and the dummy pixel pattern, so that pixels are separated from each other, thereby inhibiting crosstalk and noise.

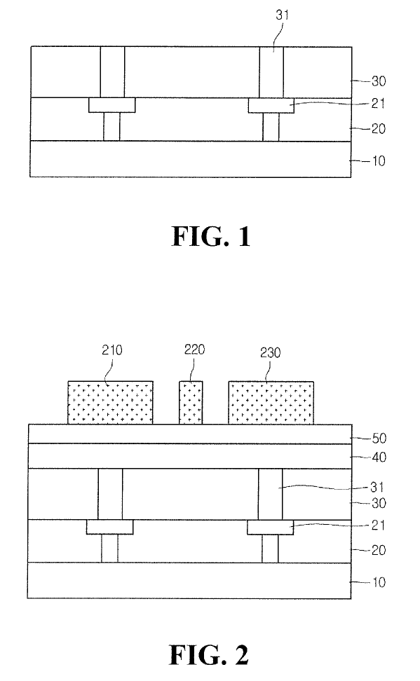

A process of manufacturing an image sensor according to an embodiment of the present invention will be explained with reference to FIGS. 1 to 6.

Referring to FIG. 1, a circuit region (not shown) and a lower interconnection structure 20 including a plurality of lower interconnections 21 can be formed on a semiconductor substrate 10.

An isolation layer (not shown) which defines an active region and a field region can be formed on semiconductor substrate 10, and a circuit region (not shown) including a transistor structure such as a transfer transistor for connecting with the photodiode to convert received optical charges into electrical signals, a reset transistor, a drive transistor and a select transistor can be formed on the active region of the semiconductor substrate 10.

The lower interconnection structure 20 can include a plurality of lower interconnections 21 formed in an insulating layer. The lower interconnections 21 can have a stacked structure to connect power lines or signal lines with the circuit region. Two lower interconnections 21 are illustrated in FIGS. 1 to 6 for purposes of explaining pixel structure, but embodiments should not be construed to be limited thereto.

An interlayer dielectric 30 can be formed on the lower interconnection structure 20.

A plurality of metal interconnections 31 pass through the interlayer dielectric 30 to be connected with lower interconnections 21 of the lower interconnection structure 20. The metal interconnections 31 can connect to the circuit region.

The metal interconnection 31 can be formed of metal, such as copper or tungsten.

After forming the metal interconnection 31 on the interlayer dielectric 30, the interlayer dielectric 30 and the metal interconnection 31 are planarized by a chemical mechanical polishing (CMP) process.

The next processes involve forming photodiodes above the metal interconnections 31.

The photodiodes are formed to convert the incident light received from outside into electric signals and store the light. In an embodiment, a PIN diode is used as the photodiode. In another embodiment a PIM structure can be utilized.

The PIN diode has a stacked structure of an n-type amorphous silicon layer (the “N”), an intrinsic amorphous silicon layer (the “I”), and a p-type amorphous silicon layer (the “P”). The PIM diode does not include the n-type amorphous silicon layer the (“N”). Rather, a lower metal electrode is used (the “M”). The performance of the photodiode is determined based on the efficiency of receiving light from the outside and converting the light into electrical signals, and gross storage charge capacitance. The related art photodiode formed in a substrate generates and stores charges in a depletion region which is created by hetero-junction, such as NP, NPN and PNP. However, the PIN diode is a photodiode having a structure including the intrinsic amorphous silicon layer, which is an intrinsic semiconductor, interposed between the p-type silicon layer and the n-type silicon layer. The intrinsic amorphous silicon layer provided between the p-type silicon layer and the n-type silicon layer serves as the depletion region to generate and store charges.

According to embodiments of the present invention, a PIN or PIM diode is used as the photodiode. The PIN diode can be formed in a PIN structure or a NIP structure. According to the embodiments described with respect to FIGS. 2-6, a PIN diode having the PIN structure is used as an example, but embodiments of the present invention are not limited thereto.

Referring to FIG. 2, a lower electrode layer 40 can be formed on the interlayer dielectric 30 having the metal interconnections 31. The lower electrode layer 40 can be formed by depositing a metal on the interlayer dielectric 30. The metal can be, for example, Cr, Ti, TiW, Ta, Cu, Al, Mo, W, or TiN. In one embodiment, the lower electrode layer 40 is formed of Cr by performing Physical Vapor Deposition (PVD). For example, the lower electrode layer 40 can be formed in a thickness of 100 Å to 5000 Å by performing the PVD process using Cr.

Then, a first conductive layer 50 can be formed on the lower electrode layer 40. The first conductive layer 50 can be the n-doped amorphous silicon. However, embodiments are not limited thereto. That is, the first conductive layer 50 can be prepared in the form of a-Si:H, a-SiGe:H, a-SiC:H, SiN:H, or a-SiO:H by adding germanium, carbon, nitride or oxygen to the amorphous silicon (where a-Si denotes amorphous silicon).

The first conductive layer 50 can be formed by a Chemical Vapor Deposition (CVD) such as PECVD (plasma enhanced CVD). In an embodiment, the first conductive layer 50 can be formed by using the amorphous silicon to have a thickness of 10 Å to 1000 Å through performing a PECVD process at a temperature of 100° C. to 400° C., using gas obtained by mixing silane (SiH₄) gas with PH₃ gas or P₂H₅ gas.

For embodiments not utilizing an additional conductive layer 50, such as for a PIM structure, the lower electrode layer 40 can be used as the pixel pattern. In such an embodiment the lower electrode layer 40 is preferably formed of Cr, Mo, or W for the “M” portion. The lower electrode layer can be silicided to reduce the dangling bonds at the interface between the metal and the intrinsic silicon layer. Accordingly, the metal layer can be a metal capable of forming a silicide at a low temperature such as not more than 400° C., preferably not more than 300° C. The silicidation of this metal layer occurs during the subsequent deposition of the “I”-layer.

Referring again to FIG. 2, a photoresist pattern can be formed on the first conductive layer 50.

The photoresist pattern includes a pixel pattern mask 210, 230 for forming pixel patterns A connected with metal interconnections 31, and a dummy pixel mask 220, for forming dummy pixel patterns B, which is formed between adjacent pixel pattern masks 210, 230 to separate the pixels from each other.

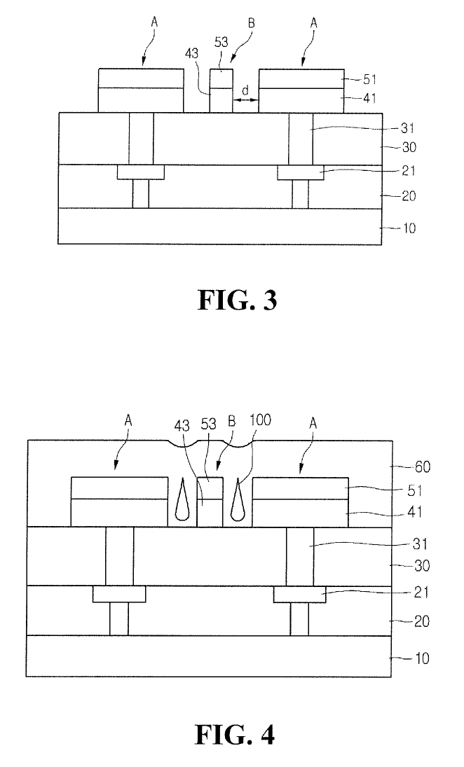

Referring to FIG. 3, the first conductive layer 50 and the lower electrode layer 40 are etched using the pixel pattern masks 210 and 230 and the dummy pixel mask 220 as etching masks. Thus, a pixel pattern A can include a lower electrode 41 connected with a metal interconnection 31 and a first conductive layer pattern 51 on the lower electrode 41. In addition, a dummy pixel pattern B, which is not connected to a metal interconnection 31, can include a lower electrode 43 formed on the interlayer dielectric 30 and a first conductive layer pattern 53 on the lower electrode 43.

The pixel pattern A formed as described above may define a unit pixel region connected with the transistor structure provided at a lower portion of the pixel pattern A.

In particular, since the dummy pixel pattern B is formed between the pixel patterns A, the unit pixels can be distinctly separated from each other, and thus the light incident onto a predetermined pixel pattern A can be inhibited from being transferred to adjacent pixel patterns, thereby inhibiting crosstalk phenomenon.

According to embodiments of the present invention an interval (d) between a pixel pattern A and the dummy pixel pattern B is smaller than half the thickness of the pixel pattern A. For example, if the thickness of the pixel pattern A is 7500 Å, then the interval (d) is less than 3750 Å.

In an embodiment, a plasma treatment can be performed after forming the pixel pattern A and the dummy pattern B. The plasma treatment can be performed to treat the surface of an n-type amorphous silicon layer.

Referring to FIG. 4, an intrinsic layer 60 is formed on the interlayer dielectric 30 on which the pixel pattern A and the dummy pixel pattern B are formed. The intrinsic layer 60 serves as an “I” layer of the PIN diode employed in this embodiment.

The intrinsic layer 60 can be formed of intrinsic amorphous silicon. The intrinsic layer 60 can be formed by CVD, such as PECVD. For example, the intrinsic layer 60 can be formed with amorphous silicon through PECVD using silane gas (SiH₄). In embodiments, the intrinsic layer 60 can be formed with a thickness ranging from about 1000 Å to 20,000 Å to serve as the depletion region for storing and generating charges.

Meanwhile, the region d between the pixel pattern A and the dummy pixel pattern B is significantly narrow, so that the intrinsic layer 60 is not easily filled in the region d when depositing the intrinsic layer 60. Thus, an air gap 100 such as a void can be formed.

Since the air gap 100 is formed between the pixel pattern A and the dummy pixel pattern B, the intrinsic layer 60 can be significantly separated by means of the air gap 100 and the dummy pixel pattern B, thereby inhibiting crosstalk phenomenon between the pixels.

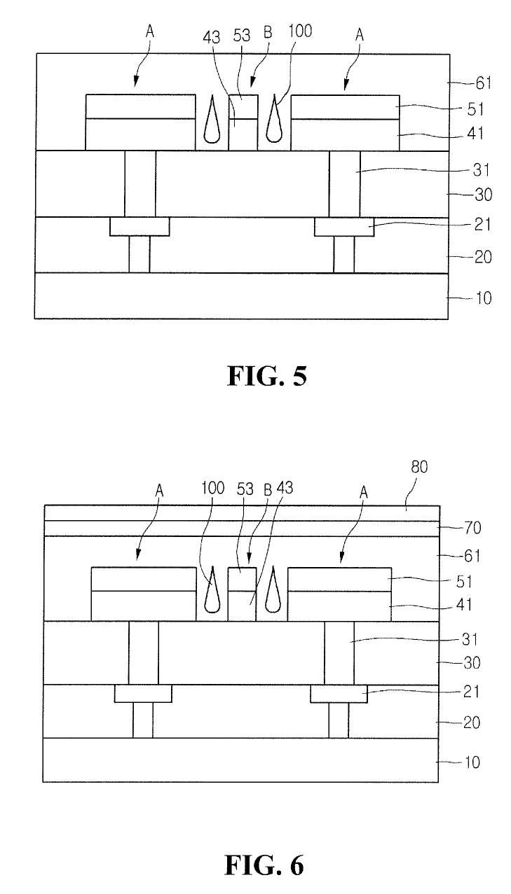

Referring to FIG. 5, the intrinsic layer 60 is planarized through a CMP process. For example, the intrinsic layer 60 can be reduced to the intrinsic layer 61 having a thickness in the range of about 1000 Å to about 10,000 Å.

Referring to FIG. 6, a second conductive layer 70 can be formed on the intrinsic layer 61. The second conductive layer 70 is consecutively formed after the intrinsic layer 60 is formed. The second conductive layer 70 can serve as a “P”-layer of the PIN diode. That is, the second conductive layer 70 can be formed of p-type doped amorphous silicon. However, the embodiments are not limited thereto.

The second conductive layer 70 can be formed by CVD, such as PECVD. For example, the second conductive layer 70 can be formed by using amorphous silicon through performing a PECVD process at a temperature of 100° C. to 400° C. using a gas obtained by mixing BH₃ gas or B₂H₆ gas with the silane (SiH₄) gas in such a manner that the second conductive layer 70 has a thickness of 50 Å to 5000 Å.

As described above, a photodiode including the first conductive layer 51, the intrinsic layer 61 and the second conductive layer 70 is formed on the metal interconnection 31, thereby improving light transmittance and focusing efficiency.

Subsequently, a transparent electrode layer having high light transmittance and high conductivity can be formed on the second conductive layer 70 to serve as the upper electrode 80 of the photodiode. For example, the transparent electrode layer can be formed of Indium Tin Oxide (ITO) or Cardium Tin Oxide (CTO). The transparent electrode layer can be formed to have a thickness of 10 Å to 1000 Å.

In addition, although not shown in drawings, according to certain embodiments, after the upper electrode 80 has been formed, a color filter array, a planarization layer and a micro-lens can also be formed.

In the method of manufacturing the image sensor according to embodiments of the present invention, the photodiode is formed on the metal interconnection, so that the fill factor approximately reaches 100%.

In addition, each unit pixel according to an embodiment can realize a complex circuit without reducing sensitivity.

As described above, the photodiode is formed on the metal interconnection, so that light transmittance is capable of being maximized.

In addition, the circuit region and the photodiode are vertically integrated, so that the fill factor approximately reaches 100%.

According to embodiments of the present invention, in order to separate the pixels from each other, the dummy pixel pattern is formed between pixel patterns, so that the devices on the unit pixels are separated between the unit pixels, and an air gap is formed between the pixel pattern and the dummy pixel pattern so as to allow light to direct to a desired pixel area which reduces cross-talk.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate having a circuit region;
an interlayer dielectric including a plurality of metal interconnections formed on the semiconductor substrate;
a plurality of pixel patterns on the interlayer dielectric and connected to corresponding metal interconnections of the plurality of metal interconnections; and
a dummy pixel pattern formed between adjacent pixel patterns of the plurality of pixel patterns.

2. The image sensor according to claim 1, further comprising:
an intrinsic layer and a second conductive layer formed on the plurality of pixel patterns and the dummy pixel pattern; and
an upper electrode on the second conductive layer.

3. The image sensor according to claim 2, wherein the upper electrode comprises a transparent electrode material.

4. The image sensor according to claim 1, wherein pixel patterns of the plurality of pixel patterns each comprise:
a lower electrode contacting the corresponding metal interconnection; and
a first conductive layer.

5. The image sensor according to claim 4, wherein the first conductive layer is an n-type conductive layer.

6. The image sensor according to claim 1, wherein pixel patterns of the plurality of pixel patterns each comprise:
a lower electrode contacting the corresponding metal interconnection, wherein the lower electrode is formed of a metal capable of being silicided at a low temperature.

7. The image sensor according to claim 1, wherein the dummy pixel pattern comprises a lower electrode material formed on the interlayer dielectric.

8. The image sensor according to claim 1, wherein the dummy pixel pattern comprises a lower electrode material formed on the interlayer dielectric and a first conductive layer on the lower electrode material.

9. The image sensor according to claim 1, wherein an air gap is formed between the dummy pixel pattern and the adjacent pixel patterns.

10. A method of manufacturing an image sensor, comprising:
forming an interlayer dielectric including a plurality of metal interconnections on a semiconductor substrate having a circuit region;
forming a plurality of pixel patterns connected to corresponding metal interconnections of the plurality of metal interconnections; and
forming a dummy pixel pattern between adjacent pixel patterns of the plurality of pixel patterns when forming the plurality of pixel patterns.

11. The method according to claim 10, wherein forming the plurality of pixel patterns and forming the dummy pixel pattern comprises:
depositing a lower electrode material layer;
forming a first conductive layer on the lower electrode material layer;
forming an etch mask on the first conductive layer; and
etching the first conductive layer and the lower electrode material layer using the etch mask.

12. The method according to claim 11, wherein forming the first conductive layer comprises depositing n-doped amorphous silicon using a chemical vapor deposition (CVD) process.

13. The method according to claim 11, wherein the first conductive layer comprises a-Si:H, a-SiN:H, a-SiGe:H, a-SiO:H, or a-SiC:H.

14. The method according to claim 10, wherein forming the plurality of pixel patterns and forming the dummy pixel pattern comprises:
depositing a lower electrode material layer;
forming an etch mask on the lower electrode material layer; and
etching the lower electrode material layer using the etch mask.

15. The method according to claim 10, further comprising:
forming an intrinsic layer on the plurality of pixel patterns and the dummy pixel pattern;
forming a second conductive layer on the intrinsic layer; and
forming an upper electrode on the second conductive layer.

16. The method according to claim 15, wherein an air gap forms in the intrinsic layer between the dummy pixel pattern and the adjacent pixel patterns when forming the intrinsic layer.

17. The method according to claim 10, wherein an interval between the dummy pixel pattern and an adjacent pixel pattern is smaller than half a thickness of the pixel pattern.
